(19) United States
(12) Patent Application Publication
(10) Pub. No.: US 2005/0181209 A1
(43) Pub. Date: Aug. 18, 2005

(54) Nanotube-containing composite bodies, and methods for making same

(76) Inventor: Prashant G. Karandikar, Avondale, PA (US)

Correspondence Address: Jeffrey R. Ramberg, Esq.;M Cubed Technologies, Inc., 1 Tralee Industrial Park, Newark, DE, 19711, US

(21) Appl. No.: 10/832,823

(22) Filed: Apr. 26, 2004

Related U.S. Application Data
(63) Continuation-in-part of application No. 10/073,818, filed on Feb. 11, 2002.
Application No. 10/073,818 is a continuation-in-part of application No. 09/378,367, filed on Aug. 20, 1999, now Pat. No. 6,355,340.

(51) Int. Cl. B32B 9/00; C23C 16/00

(52) U.S. Cl. 428/408; 427/255.12; 427/249.3; 427/900

(57) ABSTRACT

A composite material featuring carbon nanotubes reinforcing a matrix featuring metal or silicon carbide, or both. Such composites can be produced using a molten silicon metal infiltration technique, for example, a siliconizing or a reaction-bonding process. Here, the carbon nanotubes are prevented from chemically reacting with the silicon infiltrant by an interfacial coating disposed between the carbon nanotubes and the infiltrant. Preferably, the coating is free carbon or a carbonaceous precursor material added during preform processing, or after. The reaction-bonding system is designed such that the molten infiltrant of silicon metal or silicon alloy reacts with at least some of the interfacial carbon layer to form in-situ silicon carbide, and that the formed SiC is sufficiently dense that it effectively seals off the underlying carbon nanotube from exposure to additional molten infiltrant. A reaction-bonded composite body containing even a small percentage of carbon nanotubes possessed a significant increase in electrical conductivity as compared to a reaction-bonded composite not containing such nanotubes, reflecting the high electrical conductivity of the nanotubes.

### CROSS-REFERENCE TO RELATED APPLICATIONS

This patent document is a Continuation-in-Part of Copending U.S. patent application Ser. No. 10/073,818, filed on Feb. 11, 2002, which is a Continuation-in-Part of Copending U.S. patent application Ser. No. 09/378,367, filed on Aug. 20, 1999. The entire disclosures of these commonly owned patent applications are hereby incorporated by reference.

### STATEMENT REGARDING FEDERALLY SPONSORED RESEARCH OR DEVELOPMENT

This invention was made with Government support under Grant No. N00014-02-1-0960 awarded by the U.S. Office of Naval Research. The Government has certain rights in the invention.

### BACKGROUND OF THE INVENTION

1. Field of the Invention

The present invention relates to metal and/or ceramic containing composite materials featuring a particular kind of fibrous reinforcement. In particular, the invention relates to composites having a matrix featuring metal and/or ceramic, and being reinforced with nanotubes, and preferably carbon nanotubes.

2. Discussion of Related Art

It has been known for a long time to add fibrous reinforcement to metals to increase mechanical properties such as specific strength and specific stiffness. One of the early such reinforcements was carbon or graphite fiber, produced from polymer precursors. The resulting composite material offered double or triple the strength or stiffness compared to the bulk, unreinforced metal. Processing was difficult, however, as the metals either tended not to wet the carbon fibers, or reacted with the carbon. Considerable energy has been devoted to developing ways to preserve the chemical and physical integrity of the fibers while rendering them more chemically compatible with the metal matrix.

Carbon fibers can be manufactured with high degrees of anisotropy. The graphite form of carbon in particular features a hexagonal crystallographic structure, with the covalent bonds within the {001 } planes being strong, and the bonds between the {001 } planes consisting of weak van der Waals bonds. It is possible to preferentially align the crystallographic planes in a graphite fiber such that the {001 } planes tend to be parallel to the graphite fiber axis. By increasing the relative amount of covalent bonds in the fiber axis direction, a fiber possessing high strength and high elastic modulus in the direction of the fiber axis is produced. An interesting phenomenon that accompanies the alignment of the high strength, high modulus directions is that this particular direction also possesses a (rare) negative CTE. Thus, instead of expanding upon heating like most materials, these fibers actually shrink in the axial direction. In the radial direction of such fibers, however, the strength and elastic moduli are relatively low and the CTE is positive and relatively high. Because of the axial stiffness, the properties of the composites tend to be dominated by the axial properties.

When a reinforcement material having a negative CTE is incorporated into a composite material whose matrix component has a positive CTE, the individual CTE's tend to offset or cancel one another, yielding a composite or overall CTE somewhere between the two values. Because of this counterbalancing or offset effect, it is theoretically possible to engineer a metal matrix composite material, such as a metal-ceramic composite material, to have a net overall CTE of zero.

U.S. Pat. No. 3,807,996 to Sara teaches a carbon fiber reinforced nickel matrix composite material. Sara discloses the use of high strength, high modulus carbon fibers, as well as various geometrical arrangements of the fibers, such as arrays (plates) of parallel fibers and cross-plies (laminates) of such arrays.

In U.S. Pat. No. 4,791,076 Leggett et al. discloses a graphite fiber/silica matrix composite composition having a near-zero overall CTE. In addition to silica, the matrix contains boron phosphate and beta-spodumene, and Leggett states that the composite CTE is tailorable between −1 and +1 ppm/K by varying the matrix composition. As a consequence of the low CTE, very little thermal distortion occurred in for example, a laser mirror application, particularly at low coolant flow rates. This glass matrix composite material exhibited much less thermal distortion than did other laser mirror materials such as single crystal molybdenum or silicon. Although the cooling requirements were reduced, active cooling techniques involving heat transfer media flowing through channels in the mirror still were required.

As mentioned above, glass matrix composites have been used in environments where low expansion polymer composites would be insufficiently durable. Many of these applications, however, require high thermal conductivity, and most glasses are deficient in this area. Thus, composites workers have attempted to address the thermal conductivity problem by relying on the carbon fibers to carry this responsibility, the carbon fibers possessing relatively high thermal conductivity in the fiber axis direction. Another problem with glass matrix composites, though, is that they tend to be brittle. In many applications in which such composites are subjected to accelerations and stresses, such as with semiconductor fabrication equipment, it would be preferable to have a tougher, more impact resistant material.

Silicon carbide composites have been produced by reactive infiltration techniques for more-than thirty-five years. In general, such a reactive infiltration process comprises contacting molten silicon with a porous mass containing silicon carbide plus carbon in a vacuum or an inert atmosphere environment. A wetting condition is created, with the result that the molten silicon is pulled by capillary action into the mass, where it reacts with the carbon to form additional silicon carbide. This in-situ silicon carbide typically is interconnected. A dense body usually is desired, so the process typically occurs in the presence of excess silicon. The resulting composite body thus comprises silicon carbide and unreacted silicon (which typically also is interconnected), and may be referred to in shorthand notation as Si/SiC or RBSC (denoting “reaction-bonded silicon carbide”).

In one of the earliest demonstrations of this technology, Heyroth (U.S. Pat. No. 2,431,326) subjected a carbon body, in which at least a substantial portion of the carbon formed a continuous skeletal structure, to the action of elemental silicon at a temperature well above the melting point of silicon. The silicon rapidly infiltrated the whole carbon body. Furthermore, it reacted with the carbon to form a body featuring a continuous, reticular, skeletal body of crystalline silicon carbide, with the interstices of the silicon carbide skeletal structure substantially filled with silicon-rich material.

In another early demonstration of this technology, Popper (U.S. Pat. No. 3,275,722) produced a self-bonded silicon carbide body by infiltrating silicon into a porous mass of silicon carbide particulates and powdered graphite in vacuo at a temperature in the range of 1800 to 2300 C.

Over the years, there has been a significant amount of work directed to reinforcing SiC composites, e.g., reaction-bonded SiC composites, with carbon fibers. See, for example, U.S. Pat. Nos. 4,118,894; 4,944,904 and 6,248,269. Because the matrices of these composite materials consist of low CTE substances, i.e., SiC, typically interconnected, and typically also some residual, unreacted Si, also typically interconnected. More recently, work on carbon fiber reinforced Si/SiC composites has been undertaken with an eye toward brake components, e.g., brake discs and brake pads, for vehicle applications. For example, U.S. Pat. No. 6,248,269 to Dietrich et al. discloses a reaction-bonded SiC composite suitable for braking applications, e.g., disk and pad, for motor vehicles, consisting of carbon fibers arranged isotropically and embedded in a matrix of 40-50 volume percent SiC and not more than 15 volume percent Si. U.S. Pat. No. 6,261,981 to Dietrich et al. discloses a process for making such composites whereby short carbon fibers, optionally coating with a sizing, are bundled together and the bundles infiltrated or at least coated on their exterior surfaces with a binder that is suitable for pyrolysis, drying this binder, mixing the binder impregnated fiber bundles with a first filler and a second binder, pressing the mixture to form a green body, pyrolyzing the body to produce a porous fiber-reinforced carbon body, and then infiltrating the body with molten silicon. Dietrich claims substantial retention of individual filaments within the fiber bundles, and the short fiber bundles are surrounded by a coating of carbon that has reacted partially or completely with the metallic matrix material.

U.S. Pat. No. 6,030,913 to Heine discloses a similar technology. Here, the long or short high-strength graphite fibers are impregnated or coated with synthetic resin to form a pre-preg, which is then carbonized. The carbonized pre-preg is then re-subjected to further resin infiltration, and recarbonization, followed by graphitization, which is then followed by comminution to yield a dry material, which is then mixed with a high carbon content binder and compression molded to form a green article. The green article is then carbonized once more, and then infiltrated with molten silicon. The formed composite body features a matrix substantially consisting of SiC, and being reinforce with short graphite fibers. The fibers are enclosed by at least two shells of graphitized carbon, the outermost shell being partially converted into SiC.

U.S. Pat. No. 4,944,904 to Singh et al. discloses a similar composite material system intended mostly for high temperature, aerospace applications, such as a turbine engine component, but also mentioning applications such as wear parts and acoustic parts. The matrix comprises at least 5 volume percent SiC but preferably at least 45 percent, and 1-30 volume percent Si but preferably 1-2 percent. The fibers may be carbon or SiC, but are not disclosed as being arranged isotropically or quasi-isotropically. The fibers are protected from attack by the molten silicon using boron nitride plus an overcoat of a silicon-wettable material such as carbon or metal carbides such as SiC. The BN also provides a debond layer so that the fibers can move relative to the matrix under mechanical loading, thereby providing a toughening aspect to the resulting composite body.

Commonly owned U.S. patent application Ser. No. 10/073,818, filed on Feb. 11, 2002, is the parent of the present patent document. This Application has among its objectives, the production of low CTE, high thermal conductivity materials. This Application teaches that, for composite materials systems made by a molten silicon infiltration process, the CTE of the resulting composite generally is inherently low, and that even if the carbon fibers are not of the high modulus, negative CTE variety, one can still make a very low CTE material. Further, this Application discloses a simple, low cost method for protecting the low cost carbon fibers, namely, by providing a carbon coating to the carbon fibers. The carbon coating can be achieved as simply as coating the carbon fibers with a phenolic resin, and pyrolyzing the resin to carbon.

Recently, it has become known to alloy the infiltrant metal used to make a reaction-formed silicon carbide body so that the metal phase of the formed body includes a constituent other than silicon. For example, commonly owned U.S. Pat. No. 6,503,572 teaches that the infiltrant may comprise an alloy of silicon and aluminum to yield a phase in the formed silicon carbide body comprising metallic aluminum or aluminum plus silicon. Such bodies containing an alloy infiltrant phase advantageously permit certain properties of the body to be tailored to meet specific needs. For example, by replacing some of the residual silicon infiltrant with aluminum, the thermal conductivity and the fracture toughness of the composite body each may be increased.

Nanomaterials such as carbon nanotubes, sometimes abbreviated as “CNTs”, are relatively new materials that have attracted the attention of materials investigators, in part due to the potential for achieving extremes of properties. A review of the carbon nanotube literature indicates or at least suggests elastic modulus approaching that of diamond, thermal conductivity being about double that of diamond, strength being one to two orders of magnitude larger than that of steel, and electric current carrying capacity being three orders of magnitude greater than that of copper. See, for example:
1. P. G. Collins, and P. Avouris, “Nanotubes for electronics,” Scientific American, 283 (6) 2000, pg. 62-69.
2. MMJ Treacy, T. W. Ebbesen, and T. M. Gibson, “Exceptionally high Young's modulus observed for individual carbon nanotubes,” Nature 381 (1996) pg. 680-687.
3. E. W. Wong, P. E. Sheehan, C. M. Lieber, “nanobeam mechanics:elasticity, strength and toughness of nanorods and nanotubes,” Science 277 (1997) pg. 1971-1975.
4. R. S. Ruoff and D. C. Lorents, “Mechanical and thermal properties of carbon nanotubes,” Carbon 33 (7) 1995 pg. 925-930.
5. M. Dresselhaus, G. Dresselhaus, P. Elkund, and R. Saito, “Carbon Nanotubes,” Physics World January 1998 (http://physicsweb.org/article/world/11/1/9/1)

Table I compares some physical properties of carbon nanotubes to macroscopic carbon fibers. The carbon fibers and carbon nanotubes are considered fairly representative of their respective species.

TABLE 1
Comparison of axial properties of carbon
fibers and carbon nanotubes (CNTs)

| | Carbon Fibers | | |
|---|---|---|---|
| | T300 | P120 Pitch | Carbon |
| Property | PAN based | Based | Nanotubes |
| Diameter (μm) | 7 | 10 | 0.05 |
| Density (g/cc) | 1.76 | 2.17 | ˜2.0 |
| Elastic Modulus (GPa) | 231 | 827 | 1000-1400 |
| Ultimate Tensile | 3.75 | 2.41 | 7-10 |
| Strength (GPa) | | | |
| Thermal Conductivity | 8 | 640 | >2000 |
| (W/mK) | | | |
| Coefficient of Thermal | −0.6 | −1.45 | −1 (isotropic) |
| Expansion, CTE | | | |
| (ppm/K) | | | |
| Electrical Resistivity | 18 | 2.2 | <0.1 |
| (micro-ohm-m) | | | |

T300 and P120 are BP Amoco carbon fibers.
Carbon Nanotubes are from Iljin Nanotech Co. Ltd., Seoul, S. Korea.

In addition to the obvious differences, it should be pointed out that while carbon fibers have low CTE in axial directions, they have high CTE in radial directions (12 ppm/K). CNTs, on the other hand, have low CTE in both axial and radial directions. Moreover, CNTs also have much higher strain capability and as a result, they should have higher toughness than carbon fibers.

Carbon nanotubes have the graphitic structure, e.g., each carbon atom having three nearest neighbors, and can be thought of as a graphite sheet rolled up but with the ends offset to produce a helicity or chirality.

Workers in the field of composite materials have attempted to incorporate carbon nanotubes into other materials, e.g., making composites featuring such carbon nanotubes, to make useful products having novel properties. Chang, et al, in U.S. Pat. No. 6,420,293, for example, describes the use of carbon nanotubes for reinforcing a ceramic matrix composite wherein the matrix consists of a nanocrystalline ceramic material such as a metal oxide, metal carbide, nitride, oxycarbide, oxynitride, carbonitride or oxycarbonitride, carbonate or phosphate, or a mixture of these. Curiously, when the nanotube is a carbon nanotube, the matrix cannot be silicon carbide. Chang et al. envision bearings or at least bearing surfaces, wear surfaces, cutting tools and load-bearing structural articles such as prosthetic devices, made from this nanocomposite material.

Ma et al formed a composite of 10 wt % carbon nanotubes in a silicon carbide matrix via a hot pressing route, and achieved a ten percent increase in strength and fracture toughness versus monolithic SiC ceramics.

Chen et al. produced a carbon nanotube reinforced metal matrix composite by an electroplating route.

So far, the work on composite materials featuring carbon nanotube reinforcements is still relatively scant, and no one has yet reported any large improvement in mechanical properties. The above work notwithstanding, most of the reported composite work has involved polymer matrix composites. There, workers noted that one of the problems associated with the carbon nanotubes was in properly dispersing them in the polymer matrix. The production of a composite material containing both carbon nanotubes and metal, particularly molten metal, is even more of a challenge. While a coating on a typical carbon fiber may be adequately protective against chemical reaction with a metal, particularly a molten metal, one cannot simply scale the coating/fiber system down to the typical size of a carbon nanotube because the coating will likely have insufficient thickness to be protective of the underlying nanotube. Thus, another technique(s) may be required. FIG. 1 illustrates the problem. Specifically, FIG. 1 shows the relative sizes of coated carbon fibers and carbon nanotubes in cross-section. The sizes or thicknesses of the fiber, coating and nanotube of about 7 microns, 500 nanometers and about 50 nanometers, respectively, are typical for these bodies. FIG. 1 clearly shows that even the protective coating on the carbon fibers is an order of magnitude larger than the carbon nanotubes. A small fiber-matrix reaction could be permitted in the case of fibers; however, the slightest reaction would annihilate the carbon nanotubes. The CNTs are only tens of atoms in diameter.

### OBJECTS OF THE INVENTION

Thus, in view of the present state of materials development, it is an object of the present invention to produce a composite body, particularly a metal and/or ceramic matrix composite body featuring nanotubes, particularly carbon nanotubes, as a reinforcement.

It is an object of the invention to produce a nanotube-containing composite material in which the carbon nanotubes are protected from their environment, particularly during processing.

It is an object of the invention to produce a metal-ceramic composite material by an infiltration process, e.g., in which a matrix for the composite is formed as a result of infiltrating a substance into a porous mass containing the reinforcement component.

It is an object of the invention to produce a nanotube-containing composite body, and in which one or more properties of the resulting composite material has been significantly influenced by the presence of the nanotubes.

It is an object of the present invention to produce a material having a relatively high electrical conductivity.

It is an object of this invention to produce composite materials that are tougher and/or more impact resistant than similar composites without nanotubes.

### SUMMARY OF THE INVENTION

These and other objects of the present invention are achievable by producing a composite material featuring a matrix component that includes metal or silicon carbide, or both, and a reinforcement component that includes carbon nanotubes. The composite body preferably is made by an infiltration approach, more preferably by infiltration of a silicon-containing metal into a porous mass or preform, and most preferably by the reactive infiltration of a silicon-containing infiltrant into a porous preform containing the carbon nanotubes and a source of carbon (other than that of the nanotubes) available for reaction with the silicon. The carbon nanotubes may feature one or more coatings that serve to prevent chemical reaction with the molten infiltrant material. In the free carbon embodiment, the carbon source, which may also make up the nanotube protective material, reacts with the silicon of the infiltrant to form at least some silicon carbide phase in-situ in the developing composite body.

The carbon nanotubes can be mixed with one or more filler materials, such as silicon carbide or boron carbide particulate, and with any binders necessary for making a self-supporting preform. The one or more protective coatings may be applied before, during or after mixing with the filler(s).

The resulting composite body contains the carbon nanotubes as a reinforcement component of the composite, optionally one or more coatings protective of the nanotubes, a matrix featuring the silicon-containing infiltrant, and optionally one or more filler materials, also belonging to the reinforcement component. When the preform contains free carbon, the resulting composite also contains as part of the matrix component some in-situ formed silicon carbide replacing some, up to substantially all, of the elemental silicon constituent of the infiltrant component.

### BRIEF DESCRIPTION OF THE FIGURES

FIG. 1 is an illustration that shows the relative diameters of carbon fibers and carbon nanotubes.

FIG. 2 is a scanning electron micrograph of as-received carbon nanotubes.

FIG. 3 is a scanning electron micrograph (SEM) of a carbonized CNT/phenolic preform of Example I showing numerous CNTs.

FIG. 4 is a SEM of a fracture surface of a CNT/SiC composite made in accordance with Example I, showing numerous CNTs.

FIG. 5 is a SEM of a fracture surface of a CNT/SiC composite made in accordance with Example II, showing numerous CNTs.

FIGS. 6A and 6B are photographs of the composites formed in Example II and Comparative Example II, respectively, showing the macroscopic visual effect of the presence and absence, respectively, of carbon nanotubes on the outward appearance of the composite body.

### DETAILED DESCRIPTION OF THE INVENTION AND PREFERRED EMBODIMENTS

The genesis of the present work was an effort to produce low thermal expansion composite materials, and preferably also possessing relatively high thermal conductivity. This earlier work concerned how to reinforce metals such as aluminum alloys with macroscopic, high modulus, negative CTE (“coefficient of thermal expansion”) fibers such as high modulus carbon fibers. As the work progressed, the investigators focused more attention on silicon as a candidate metal. Although intrinsically brittle, silicon possesses very low thermal expansion coefficient, which is particularly advantageous for applications requiring very low or near-zero CTE. With the inherently low CTE matrix material, one could obtain a low CTE composite material without having to resort to expensive, negative CTE carbon fibers. Carbon fibers having a positive (but still small) CTE were advantageously employed to yield a composite material having a CTE less than that of the silicon matrix, at greatly reduced cost compared to the negative CTE carbon fibers.

The instant invention focuses on a carbonaceous reinforcement component for the composite that is in the form of “nanotubes”. Carbon nanotubes in particular have been garnering attention recently in the materials science community. As the name suggests, the tubes are hollow and much smaller than a typical fiber, at least in terms of fiber diameter. Nanotubes typically have diameters on the scale of nanometers. They often have very high aspect ratios; that is, the ratio of their length to their diameter can be quite large. The long lengths, perhaps on the order of millimeters, can have utility for, among other properties, toughening, rapid heat transfer, and enhanced electrical conductivity.

The instant invention now describes the successful incorporation of such nanotubes into metal and ceramic based composite materials, particularly composite materials produced by an infiltration process.

Although it is probably possible to incorporate carbon nanotubes into metal and/or ceramic based composite systems by techniques such as sintering or hot pressing, etc, what is preferred according to the instant invention is an infiltration involving a molten metal such as a silicon-containing metal, such as used to make reaction-bonded silicon carbide, for instance. For example, there is likely to be at least some damage done to the carbon nanotubes during a hot pressing operation, as this typically occurs to carbon fibers that are hot pressed. Protective coatings on the fibers are especially vulnerable. Further, composite bodies made by infiltration typically exhibit much less dimensional change upon infiltration than do composite bodies made by sintering. Using this approach, nanotube volumetric loadings in the preform ranging from less than 0.1% up to 35% or more are possible, with about 1% to about 10% being particularly desirable from an economic perspective.

A particularly preferred infiltrant in the instant invention is silicon metal or silicon alloy. Not only does silicon possess low CTE, important for many of the applications contemplated by the instant inventor, but, depending on the other processing conditions, one can use this infiltrant system to produce predominantly metal-based composite bodies, or predominantly ceramic-based composite bodies. For example, molten silicon can spontaneously wick into a porous mass of silicon carbide without the need to draw the molten silicon in under vacuum or to force it in under pressure. See, for example, U.S. Pat. No. 3,951,587 to Alliegro et al. The instant invention refers to this product as “siliconized SiC”, and to the process by which it is made as “siliconizing.” This infiltration works best in a vacuum atmosphere. When the porous mass contains some free or reactable carbon that is available to react chemically with the molten silicon, the infiltration usually is enhanced and the process generally is more robust. At least at some point during the infiltration, the silicon component of the infiltrant chemically reacts with at least a portion of the carbon in the porous mass to form silicon carbide. The body thus formed features the porous mass material, typically silicon carbide, distributed throughout the in-situ silicon carbide formed from the chemical reaction. Typically, some infiltrant material remains in the infiltrated body, and distributed throughout. The instant invention refers to this metal-ceramic composite material product as “reaction-bonded SiC”, and to the process by which it is made as “reaction-bonding”, although other terms have been used in the literature over the years to mean substantially the same thing. These terms include “reaction forming”, “reaction sintering”, and “self bonding”. Both the siliconizing and the reaction-bonding processes are within the scope of the instant invention.

A common technique for producing metal composites by infiltration, at least for aluminum-based metal composites, utilizes an externally applied force such as external pressure to help the molten metal permeate the preform. This, too, is within the scope of the instant invention.

In the prior work with carbon fibers (not nanotubes), one of the issues that arose with attempts to make metal or ceramic composites by infiltration that are reinforced with such carbon fibers was that the principal constituent of the infiltrants of the present invention, namely silicon, tends to react with the carbon fibers. (Strictly speaking, silicon is a semimetal or “metalloid”, but in the context of the present invention, silicon will be considered a metal.) In the embodiment in which the silicon is one of two or more constituents of the molten infiltrant metal, the same is true for the most common alloying element for the instant silicon infiltrants, namely, aluminum. Aluminum, for example, reacts with carbon to form aluminum carbide. Not only does this represent a chemical degradation of the graphite reinforcement fibers, but also aluminum carbide is hygroscopic. The chemical conversion of aluminum carbide to aluminum hydrate from exposure to water (such as water vapor, e.g., humidity) produces acetylene gas plus a large positive volume change that can cause cracking in the composite body.

There exists the possibility that, due to their highly ordered graphitic structure, the carbon nanotubes may possess higher-than-normal resistance to chemical attack by molten silicon. However, the instant invention has proceeded on the assumption (without further analysis) that the carbon nanotubes will not have increased corrosion resistance compared to macroscopic carbon fibers. Thus, the instant inventor expects that, the nanotube diameter being many times smaller than that of a typical carbon fiber, a carbon nanotube would be completely destroyed upon contact with molten silicon. Accordingly, the present work has focused on providing one or more protective coatings to the nanotubes, just as with macroscopic carbon fibers that are to be utilized in preforms that are to be infiltrated with molten metal.

In the prior case of the macroscopic carbon fibers, the one or more coatings are placed directly onto the fibers. Sometimes, coatings can be found that also permit the infiltrant metal (e.g., aluminum) to wet the reinforcement better. Wetting of the metal to the reinforcement may improve the mechanical properties of the resulting metal composite, and the wetting condition may also permit the metal to infiltrate a porous mass of the reinforcement material without the need to force the molten metal in under pressure, or to pull it in under applied vacuum. For silicon or silicon alloy melts, a desirable additional coating is silicon carbide, and a widely known technique for depositing a coating of silicon carbide onto macroscopic carbon fibers is by chemical vapor deposition (CVD). It may be possible to similarly coat or encapsulate carbon nanotubes in such CVD SiC.

A technique that is particularly preferred according to the instant invention for protecting the carbon nanotubes when the infiltrant includes silicon, is to coat the nanotubes with, or embed them in, additional carbon prior to infiltration. Carbonaceous materials such as pitch, phenolic resin, furfural alcohol, epoxy resin, etc. are acceptable choices in this regard. One embodiment, but certainly not the only embodiment of this technique for coating nanotubes, is to stir in the nanotubes into the liquid resin. One may adjust viscosity as needed for the type of processing used by “thinning” the mixture with a low viscosity liquid into which the resin is soluble, e.g., an organic solvent.

After the mixture has been molded or cast or otherwise processed to the desired preform shape, any solvents that may have been added are removed, for example, by a drying operation, and then the carbonaceous substance (e.g., resin) is decomposed to carbon, first by curing or crosslinking the resin, and then with further heating, generally in a non-oxidizing environment, to pyrolyze the resin to drive off the non-carbon constituents of the resin, leaving substantially pure carbon behind as a residue. The residue carbon generally is porous, which may be important for a silicon infiltration operation. However, the pores are of such a size and amount and arrangement as to permit molten silicon infiltration into the pore space of the preform but not to permit complete chemical reaction of the silicon with carbon. Thus, it may be inevitable that some of the pyrolyzed carbon reacts with molten silicon during infiltration, but typically not all of this carbon is so reacted. That the pyrolyzed carbon limits the degree of reaction during infiltration of molten silicon is a manifestation of its protective function. It is not necessary that the pyrolyzed carbon be provided in multiple layers, or be in graphitized form for it to serve this chemical protective function.

Optionally, it may be desirable to add a supplemental source of carbonaceous material not containing nanotubes to the developing preform. Specifically, this supplemental carbon may be provided for the purpose of reacting with the silicon metal of the infiltrant to form in-situ silicon carbide and/or for further reducing the propensity for the silicon to react with the nanotubes by saturating the silicon with carbon. One means of accomplishing this carbon addition to the preform is to soak the preform in a carbonaceous resin such as furfuryl alcohol, and then pyrolyze the resin in a non-oxidizing atmosphere to decompose the resin to essentially elemental carbon. This soak-and-pyrolyze step can be repeated one or more times to increase the amount of carbon and decrease the amount of pore space in the preform.

Moreover, it may be the case that the residual carbon also serves to permit some movement in the axial direction of the nanotubes relative to the matrix, e.g., serve as a nanotube debond layer or interface, should such behavior be desirable, for instance, if toughening is desired. A composite body whose matrix is based on silicon metal typically is brittle, and thus any toughening mechanism that can be imparted to such a composite generally is desirable.

In another embodiment, it may be possible to coat or encapsulate carbon nanotubes with a silicon-containing polymer such as a polysilazane, for example, by stirring nanotubes or clumps/clusters of nanotubes into a polysilazane resin, or soaking bulk resin into a preform containing the nanotubes.

In another technique for protecting the nanotubes, it may be the case that it is not necessary to encapsulate the nanotubes in carbon, but rather to merely saturate the molten infiltrant metal in carbon. Thus, any form of carbon in the preform (e.g., particulate) that is available to dissolve and/or react with the molten infiltrant may be helpful in preventing the nanotubes from being corroded by molten infiltrant metal.

Upon contact with the molten silicon or its alloy, the latter can infiltrate the porous preform, and the silicon can react with at least a portion (generally only a portion when done correctly) of the carbon matrix of the preform to form at least some SiC in the matrix, and typically leaving behind some residual Si or Si alloy. Ideally, the carbon nanotubes are protected from the molten silicon by the carbon matrix, thereby leaving a composite body comprising carbon nanotubes, (optionally) one or more other filler materials, and a matrix comprising SiC, Si (or a Si-containing metal) and usually also some residual carbon, mostly at the interface between the reinforcement material(s) and the Si/SiC matrix. The residual carbon coating also provides for toughening of the composite material by making a weak bond with the Si/SiC matrix, thereby permitting movement of the carbon nanotubes relative to the matrix upon application of mechanical stress.

Without wishing to be bound to any particular theory or explanation, it may be that the free carbon matrix can protect the underlying carbon nanotubes as a result of the large volume change associated with chemically converting carbon to silicon carbide. Upon chemical reaction with silicon, a unit volume of carbon forms 2.3 unit volumes of SiC. The space occupied by the formed SiC can help block off unreacted carbon from further ingress of this molten silicon.

Engineering the composite body such that at least some carbon remains unreacted by silicon can be accomplished through attention to, and control of, factors such as the relative amounts (volumetric loading) of reactable carbon and filler, the type or form of the carbon, the relative amount of infiltrant provided, the time required for infiltration and the processing temperature during infiltration. Factors that are conducive to the intentional incomplete reaction of the supplied carbon include supplying relatively large quantities of carbon to the preform, using sources of carbon that have a high char yield such as furfuryl or phenolic resins, and minimizing the processing time and temperature of infiltration.

If necessary or desirable, the carbon nanotubes of the reinforcement component of the composite body may be supplemented with one or more other filler materials. Filler materials are often provided in composite bodies to perform one or more functions such as tailor one or more properties of the composite body in a direction toward that property of the filler material, and/or to minimize the amount of space that must be occupied by matrix material. The filler material(s) could be other forms of carbon not intended to react with the infiltrant to form silicon carbide, other non-elemental carbon materials such as metal carbides, or non-carbon-containing materials such as refractory metals, borides, nitrides or oxides, or complex compounds, e.g., oxycarbides.

A popular filler morphology is that of particulate because particulate is economical and readily available, but other non-limiting morphologies include fibers, spheres, platelets and flakes. Useful sizes of particulate for metal-ceramic composite bodies made by infiltration of silicon-containing melts range from about 1 micron to about 1 millimeter.

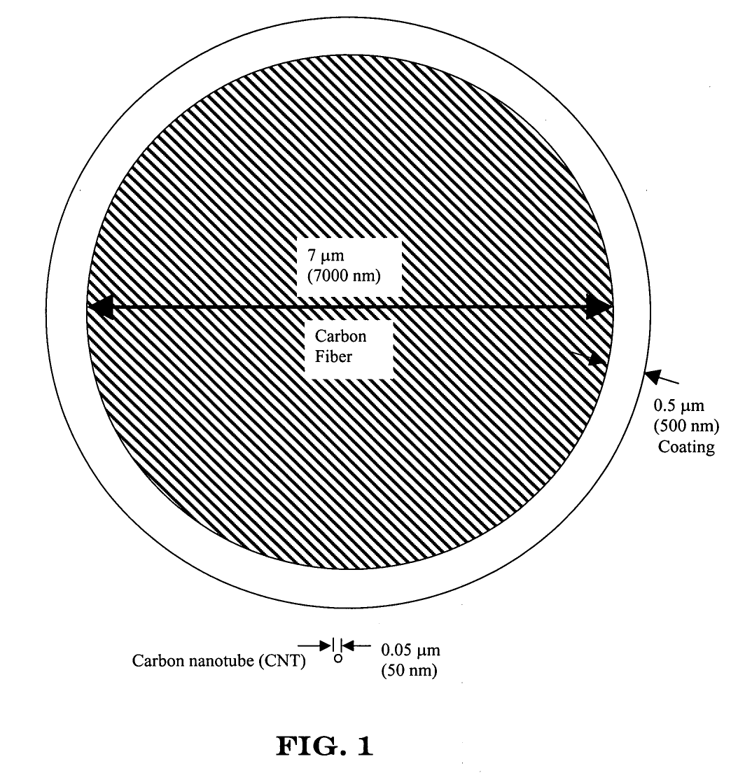

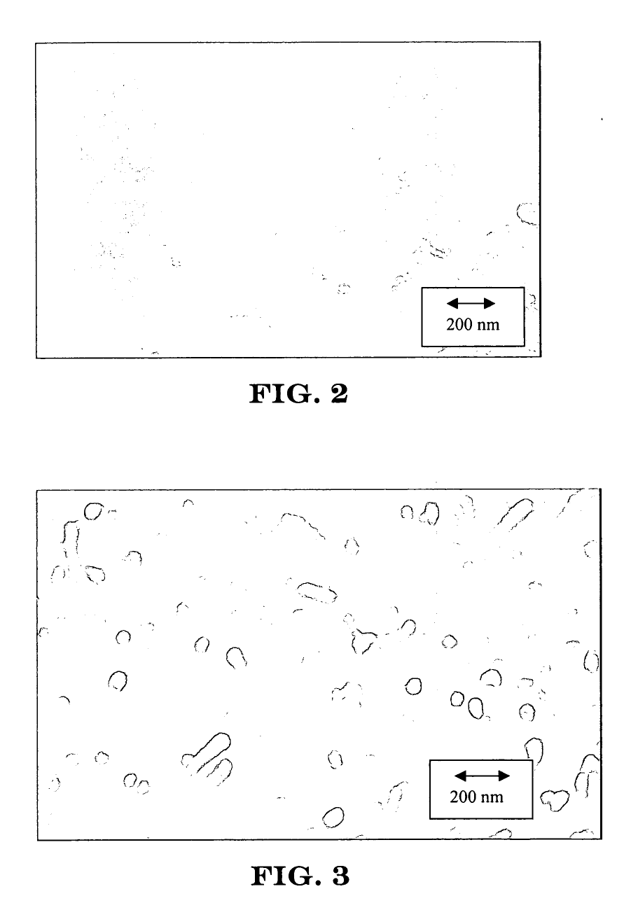

Using techniques known in the art, the total volumetric loading of filler (e.g., nanotubes plus other optional fillers) can range from about 5 or 10 vol % up to almost the limits where the pore space between bodies of filler begin to close off, about 90 or 95 vol%. More typically, a reaction-bonded composite body that is highly loaded in filler might be expected to have between about 60 and 80 vol % filler.

Where the carbon nanotubes are in discontinuous form, for example, “as provided” from the manufacturer, the nanotubes and the other fillers may simply be placed into a common container and mixed together, such as by roll mixing or dry milling. The mixture can then be shaped as a preform using techniques known in the art. However, a more sophisticated approach might take into account that the bodies of filler material generally are going to be much larger in size than the diameter of a nanotube (recall FIG. 1). Accordingly, it may make sense to first mix the nanotubes into a liquid component if one is to be used in the preforming process. Even in a dry pressing operation, there is often a liquid component used, such as the binder. (Note that in “as received” form, the dry nanotubes can be in the form of a mass of tangled nanotubes. See, for example, FIG. 2.) The mixture can then be processed in the usual way to make a preform, according to preforming techniques well-known in the art, e.g., pressing, casting (slip, sediment, tape, thixotropic, for example), injection molding, etc. If the preform is to contain free or reactable carbon, such can also be added at this time (if it has not been added already), such as by dipping the preform into a carbon-containing paint or slurry. If a preform is to be made via the prepreg route, it should be possible to incorporate the one or more filler materials into the prepreg in the same way that the nanotubes are incorporated, that is, by mixing or stirring into carbonaceous resin. Alternatively, the filler(s) may be placed between adjacent plies of prepreg material during preform development.

In an alternate route to preform development, a developing preform containing nanotubes and which is self-supporting, for example, as a result of the presence of skeletal carbonaceous material such as resin, may be infiltrated with one or more fillers that are carried into the preform with a liquid carrier fluid. For instance, a nanotube-containing preform can be infiltrated with a slurry or slip containing one or more fillers.

Preforms are useful because they more exactly define the final desired shape, and thus contribute to reducing the amount of final machining required to produce a nanotube reinforced composite article of some specific shape. A preform usually is thought of as a porous mass containing the filler or reinforcement of the composite body that has been rendered self-supporting, such as with a binder or coating of some kind. Often times, the preform has the shape, or is made to conform to the shape of the final object desired, such as by molding or so-called “green” machining. Additionally, and particularly for complex shaped articles, one may build up the larger, more complex structure from two or more smaller, simpler-shaped preforms, for example by adhesive bonding the component preforms to one another. Carbonaceous adhesives such as phenolic resin, epoxy, cyanate ester, etc. are well suited for this purpose. Further, one can add one or more filler materials, e.g., carbon fibers, SiC particulate, etc., including nanotubes, to the carbonaceous adhesive, for example, to more closely match one or more physical properties of the adhesive (e.g., CTE) to those of the component preforms.

When carbon fibers have been arranged in a sheet or film of a matrix material that is carbonaceous such as a resin, and the resin is cured, this product is sometimes referred to as a “prepreg”. Prepregs are often pliable. When the resin of the sheet or film has been pyrolyzed, the resulting product is called a “zero stage” body. Such a zero stage body is usually rigid. If a resin re-infiltration and pyrolysis step is repeated “n” times, the resulting body is referred to as an “n stage” body, where n=0, 1, 2, 3, etc. For example, for two resin re-infiltration/pyrolysis cycles, the resulting body is a “two stage” body. The present inventors are not aware of anyone offering such prepregs or n-stage bodies containing carbon nanotubes; however, it should be possible to make such prepregs/n-stage bodies. In particular, it should be possible to mix or stir the carbon nanotubes into carbonaceous resin, and then prepare a sheet or film of the resin in a cured (“prepreg”) or pyrolyzed (“n stage”) condition in the usual way. From there, a preform such as a three-dimensional structure may be produced, again, in the usual way, e.g., laminating a plurality of such sheets or films. Again, where prior art composites have been made by the reactive infiltration of silicon into a preform containing carbon to produce silicon carbide, the objective usually has been to maximize the amount of SiC and to minimize the amount of Si, e.g., for refractory applications. Since the present invention embraces the infiltration of molten silicon-containing metal into a porous preform to produce a Si-containing composite body, the practitioner has wide latitude in the kind of composite body that he or she can process. For instance, one can maximize the amount of SiC produced by providing a preform that is highly loaded in SiC reinforcement and/or producing large quantities of in-situ SiC from reaction of molten Si with reactable carbon in the preform. However, the former approach may be more desirable than the latter. Among the problems that result from excessive reaction during the infiltration process are temperature spikes due to the exothermic nature of the chemical reaction of silicon and carbon. Such temperature spikes can cause cracking due to localized thermal expansion. In addition, (and as mentioned previously) the conversion of elemental carbon to silicon carbide entails a volumetric expansion of about 2.3 times. Thus, large amounts of reaction are also detrimental from the standpoint that the large volumetric change may cause cracking.

On the other hand, where something more akin to a metal matrix composite (“MMC”) or dispersion strengthened metal has been the objective, the practitioner of the instant invention can produce this by providing a preform that is not highly loaded in ceramic reinforcement material and by minimizing the degree of reaction that the molten Si undergoes with carbon sources as it infiltrates the preform. Where the amount of free carbon in the preform is low or is substantially completely reacted, the amount of in-situ SiC formed will be relatively low, perhaps on the order of 1 to 10 vol % of the volume of the formed composite body. On the other hand, where the amount of free carbon is greater and extensive reaction ensues, the amount of residual infiltrant metal remaining in the formed body typically will be low, perhaps on the order of 5 to 20 vol % of the formed composite body. Where the free carbon in the preform is interconnected and is incompletely reacted during infiltration, the situation is complex, as the matrix of the resulting composite body can contain carbon, silicon carbide and residual infiltrant metal.

Prior investigators tended to avoid silicon as a matrix metal, favoring other, tougher metals for making MMCs. Nevertheless, where some degree of toughness is required, there are techniques for increasing toughness of a silicon matrix composite, e.g., fiber debonding or alloy modifications to the matrix phase.

A composite material that is high in silicon metal has many desirable features, and should not be overlooked or dismissed. For example, at about 2.7 ppm/K, silicon possesses a low coefficient of thermal expansion, and its thermal conductivity is relatively high at about 151 W/m K. This is a desirable combination of physical properties, for example, for many high precision applications such as optical quality mirrors. Silicon carbide also possesses these properties, but as a candidate matrix material, silicon possesses a number of advantages over silicon carbide. For example, silicon is machinable by electrodischarge machining (EDM), whereas silicon carbide is not. Moreover, some applications such as certain components in a semiconductor lithography machine, are required to be coated, such as by plating, and in this regard, silicon is easier to plate than is silicon carbide, i.e., electroplating requires electrical conductivity. Unless the application contemplated by the user is intended to operate above the ductile/brittle transition temperature of silicon (and some applications indeed are intended to so operate), the silicon component of the composite body usually is brittle. Accordingly, and unlike the situation where the matrix is tough (as it is inherently with most metals), it may be necessary to provide a toughening mechanism to the instant silicon-containing composites.

One way for enhancing the toughness of the Si-based matrix composites is to enhance the toughness of the matrix, e.g., by alloying the silicon. Commonly Owned U.S. Pat. No. 6,503,572 (discussed previously) discloses that aluminum may be alloyed with the silicon in amounts ranging from about 0.1 percent by weight or less up to about 90 percent. The resulting alloy can still infiltrate by capillarity into a porous mass of reinforcement material containing some interconnected carbon to form a reaction bonded silicon carbide composite body. The alloy generally does not need to be heated to a temperature greater than about 100° C. above its liquidus temperature. If the body to be infiltrated contains no elemental carbon, however, the process may have to be carried out at higher temperatures, for example, in the 1 600° C. to 1 800° C. range. The entire disclosure of this Commonly Owned Patent is hereby incorporated by reference.

Another technique to impart toughening is the technique commonly employed in CMC's—namely, to cause the fibers to debond from the matrix under applied load, or at least to be able to move axially with respect to the matrix under the influence of an applied load. This technique is commonly achieved with a debond layer such as carbon (e.g., pyrolytic carbon) or boron nitride applied to the fibers. However, with Si/SiC composite systems, such carbon coatings are often reactive with the molten Si infiltrant, typically resulting in the loss of the debonding property. On the other hand, some coatings, such as boron nitride in particular, may not be wetted by molten Si, thus preventing infiltration. However, since it was stated earlier that the carbon nanotube reinforcement itself is reactive with many of the candidate matrix metals and thus needs to be protected, for example, with a coating, the debond coating may be located between the nanotube and the coating that is protective of the nanotube. In this way, the protective coating may protect both carbon nanotube and debond coating. The debond coating can be applied or deposited by techniques known in the art, such as chemical vapor deposition (CVD). For macroscopic fibers, the protective coating also may be applied by CVD. U.S. Pat. No. 5,015,540 discloses such a multiple fiber coating system. It has been observed, however, that for a CVD SiC coating to be protective of NICALON® SiC fibers at about 35 vol % loading in a preform, the coating needed to be on the order of about 2 microns in thickness. (See, for example, U.S. Pat. No. 5,682,594.) This size is much larger than the diameter of a single nanotube, so this approach may not be practical, unless the CVD SiC coating is of a bundle of nanotubes such that the coating layer surrounds or envelops the entire bundle and not individual nanotubes. It bears noting that since carbon was earlier identified as a candidate protective coating, under the proper conditions it is possible that a single material, e.g., carbon, can serve the dual role of acting to chemically protect the underlying nanotube, as well as acting as the debond material for toughening purposes. Again, it seems as though carbon coating thicknesses that are merely on the order of the thickness of a single nanotube will not be sufficiently protective against chemical attack by molten silicon. Accordingly, the carbon “coating” may be provided in sufficient thickness and sufficient quantity that it might be thought of as forming a part of the matrix phase of the preform (e.g., interconnected), and not merely as a discrete coating on individual nanotubes.

The following examples illustrate with still more specificity several preferred embodiments of the present invention. These examples are meant to be illustrative in nature and should not be construed as limiting the scope of the invention.

### EXAMPLE I

This Example, demonstrates, among other things, the successful incorporation of carbon nanotubes (CNTs) into a metal-ceramic composite material and in particular, the survivability of the CNTs during infiltration processing with the metal in a molten condition.

About 3.86 g of chemical vapor deposition (CVD) grown multi wall carbon nanotubes (Iljin Nanotech Co. Ltd., Seoul, Korea) were mixed with about 42.64 g of phenolic (SC1008 from Borden Chemical Inc., Louisville, Ky.) to make a mixture. The CNTs diameter ranged from about 10-50 nm. The mixture was poured in a rubber mold with a cavity measuring about 5 by 5 by 1.3 cm. The rubber mold was placed on a vibrating table for about 12 hours. A thin TEFLON® sheet measuring about 5 cm square was placed on the mixture in the mold. A graphite block measuring about 5 by 5 by 2.5 cm (and having a mass of about 225 g) was placed on top of the TEFLON® sheet. The mold was then placed in a curing oven and heated to about 140° C. for about 3 hours and then cooled to room temperature (about 20 C).

A cured, stand-alone preform was produced after demolding. This preform was placed in a retort and heated to about 650° C. for about 2 hours in an inert atmosphere to carbonize the phenolic. Carbonization of the phenolic left a pyrolytic carbon coating on the CNTs which protects them during subsequent infiltration by molten Si.

An SEM photo of the carbonized preform is shown in FIG. 3. It clearly shows the existence of CNTs. The diameter of the CNTs is higher than that of as-received CNTs due to the pyrolytic carbon coating deposited by the pyrolysis of phenolic. Due to the high char yield of phenolic a dense pyrolytic carbon coating is formed.

This preform was then placed in a vacuum furnace, vacuum was drawn (<100 microns) and the preform was then heated to about 1520° C. and brought into contact with molten silicon.

Molten silicon quickly infiltrated into the preform. The pyrolytic carbon reacted with molten Si and provided the driving force for the infiltration. However, after initial reaction, a dense SiC coating was formed which prevented further reaction and protected the CNTs from reacting with molten Si.

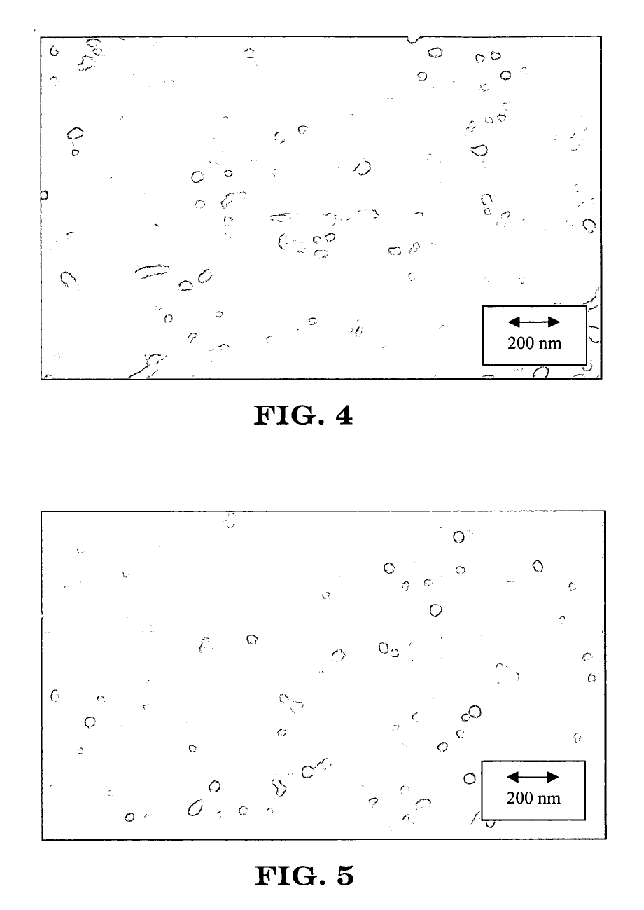

A fully dense composite resulted containing SiC, CNT, residual C and Si. FIG. 4 shows a scanning electron microscope (SEM) micrograph obtained from a fractured specimen of this composite body. The micrograph clearly shows the existence of many CNTs.

Thus, this example proves that a molten metal infiltration process can be used to make CNT/SiC composites and the pyrolytic carbon coating protects the CNTs during melt infiltration or reaction bonding.

### EXAMPLE II

This Example, demonstrates, among other things, the successful incorporation of carbon nanotubes (CNTs) into a metal-ceramic composite material also containing another filler or reinforcement material.

About 50 g of SiC powders consisting of a 70:30 weight ratio of 240 and 500 grit particulates (Saint Gobain/Norton Industrial Ceramics, Worcester, Mass.), 2 g CNTs, about 20.93 g phenolic and about 15.6 g THF (solvent) were hand mixed in a beaker to make a mixture. The mixture was poured in a rubber mold with a cavity measuring about 5 by 5 by 1.3 cm. The rubber mold was placed on a vibrating table for about 12 hours. A thin TEFLON® sheet measuring about 5 cm square was placed on the mixture. A graphite block measuring about 5 by 5 by 2.5 cm was placed on top of the TEFLON® sheet. The mold was then placed in a curing oven and heated to about 140° C. for about 3 hours and then cooled to room temperature. A cured, stand-alone preform was produced after demolding. This preform was placed in a retort and heated to about 650° C. for about 2 hours in an inert atmosphere to carbonize the phenolic. Carbonization of the phenolic leaves a pyrolytic carbon coating on the CNTs which protects them during infiltration by molten Si.

This preform was then placed in a vacuum furnace, vacuum was drawn (<100 micron) and then heated to about 1520° C. and brought in contact with molten silicon. Molten silicon spontaneously infiltrated into the preform. The pyrolytic carbon reacts with molten Si and provides the driving force for the infiltration. After initial reaction, a dense SiC coating is formed which prevents further reaction and protects the CNTs from reacting with molten Si.

A fully dense composite was obtained containing SiC (both as reinforcement and as matrix material), CNTs, Si and C. The density of the composite was found to be 2.65 g/cc. FIG. 5 shows an SEM micrograph obtained from this infiltrated, fractured specimen. The micrograph clearly shows the existence of many CNTs.

Thus, this Example proves that a metal infiltration process can be used to make a CNT-containing composite and that the pyrolytic carbon coating protects the CNTs during melt infiltration or reaction bonding. And further, the Example shows that a filler can be incorporated into the composite body without interfering with the CNTs.

### COMPARATIVE EXAMPLE II

This Example demonstrates, for comparative purposes, the manufacture of a SiC composite body not containing carbon nanotubes.

The technique of Example II was substantially repeated to produce a composite body containing SiC and Si. The mixture to be cast had the following composition: about 100 grams SiC powder, about 15 grams of the phenolic resin, and about 15 grams of ethanol. This composition had about the same viscosity as the nanotube-containing mixture of Example II.

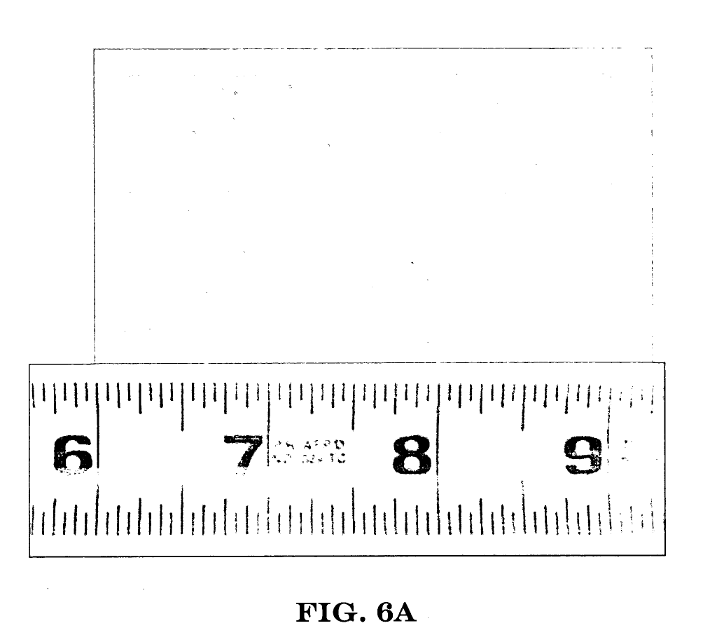

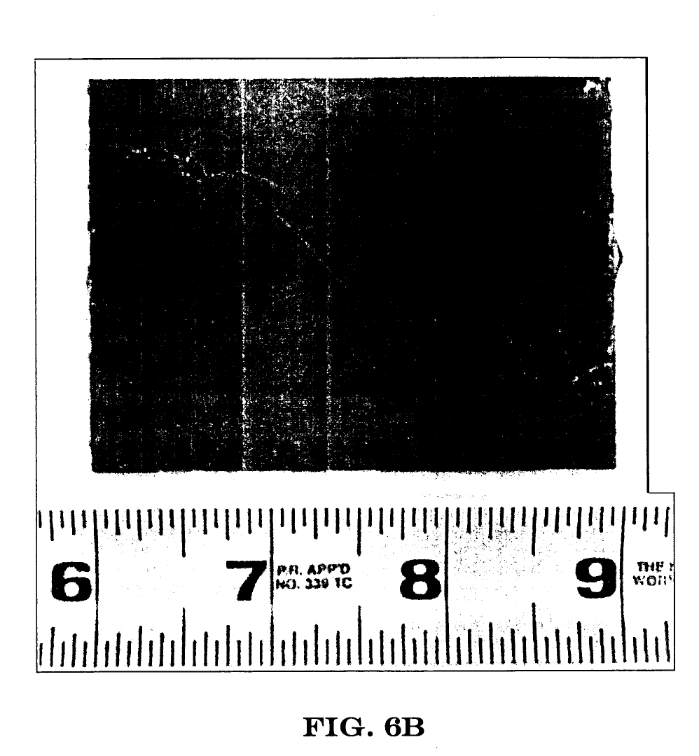

The bulk density of this composite material was about 3.04 g/cc. FIGS. 6A and 6B show a visual comparison of the composite bodies with and without nanotubes, respectively.

Right rectangular beams were machined from the composite blocks of Example II and Comparative Example II for electrical resistivity measurements. The ends of the beams were painted with a silver paste to assure good contact to the probes of a commercially available multimeter. The resistivity of the carbon nanotube-containing SiC composite material of Example II was about 2 orders of magnitude lower than that of the SiC composite not containing nanotubes, 0.0038 ohm-cm versus 0.37 ohm-cm. This should serve as additional evidence that the carbon nanotubes survived the composite-making conditions.

### INDUSTRIAL APPLICABILITY

The methods and compositions of the present invention should find utility in applications requiring or benefitting from the unusual properties offered by nanotubes, particularly carbon nanotubes, e.g., applications where high specific stiffness, low thermal expansion coefficient, enhanced toughness, high electrical conductivity, and/or high thermal conductivity are important

For certain friction products such as brakes and clutches, the carbon nanotube reinforced SiC composites of the instant invention seem to possess many of the desirable properties.

The expected toughening effect of the carbon nanotubes should also improve the characteristics of ballistic armor, such as personnel armor (“body armor”) made from carbon nanotube reinforced composites, such as those based on Si/SiC, Si/B₄C and S/SiC/B₄C. The high electrical conductivity of carbon nanotubes should also have the effect of increasing thermal conductivity of the composite bodies into which they are incorporated. Similarly, the very low, and even negative, CTE of the nanotubes should also have the effect of reducing the CTE of composite bodies into which they are incorporated.

The instant nanotube-composites should also find application in large structures that must maintain size and shape within exacting tolerances, such as mirrors, e.g., land or space-based mirrors.

Other applications in such industries as the precision equipment, robotics, tooling, aerospace, electronic packaging and thermal management, and semiconductor fabrication industries, among others, will occur to those skilled in those arts.

An artisan of ordinary skill will appreciate that various modifications may be made to the invention herein described without departing from the scope or spirit of the invention as defined in the appended claims.

1. A method for making a composite body containing carbon nanotubes, comprising:
(a) providing a porous mass comprising carbon nanotubes;
(b) contacting a source of molten infiltrant comprising silicon to said porous mass;
(c) infiltrating molten infiltrant into said porous mass; and
(d) solidifying said molten infiltrant.

2. A method for making a carbon nanotube-reinforced composite body, comprising:
(a) mixing carbon nanotubes in a polymeric resin;
(b) shaping this mixture as a preform;
(c) pyrolyzing the resin plus optional carbon source to form substantially elemental carbon;
(d) contacting said pyrolyzed preform to a source of molten infiltrant comprising silicon metal;
(e) infiltrating silicon from said source into said preform, and reacting at least a portion of said infiltrated silicon with at least a portion of said elemental carbon to form silicon carbide at the reaction interface that is sufficiently dense as to prevent continued infiltration of said molten silicon past said formed SiC; and
(f) solidifying said silicon metal in said preform.

3. A method of making a carbon nanotube-containing composite body, comprising:
(a) mixing a plurality of carbon nanotubes with at least one filler material to make a mixture;
(b) supplying at least one carbon-containing liquid to said mixture, and stirring sufficiently to substantially coat at least all of the external surfaces of the at least one filler material and the carbon nanotubes, thereby forming an admixture;
(c) organizing said admixture as a porous mass to be infiltrated;
(d) drying said admixture;
(e) contacting a molten infiltrant comprising silicon to said porous mass;
(f) infiltrating said porous mass to a desired extent with said molten infiltrant to form an infiltrated mass; and
(g) cooling said infiltrated mass to form a composite body.

4. The method of claim 1, further comprising introducing at least one source of carbon to said porous mass.

5. The method of claim 4, further comprising (a) organizing said reinforcement material to a desired bulk shape; and
(b) applying at least one coating to said nanotubes, said coating intended to protect said nanotubes from chemical reaction with molten silicon.

6. The method of claim 4, wherein said porous mass further comprises at least one filler material, thereby forming a reinforcement component for said composite, and further wherein at least a portion of said supplied carbon forms a coating on said nanotubes, said coating intended to protect said nanotubes from chemical reaction with molten silicon by substantially isolating said nanotubes from direct contact with said molten silicon; and said method further comprises organizing said reinforcement component to a desired bulk shape.

7. The method of claim 2, wherein said polymeric resin has a high char yield, and further comprising applying at least one protective coating to said preform or to the carbon nanotubes thereof.

8. The method of claim 2, wherein said molten infiltrant comprises at least one metal other than silicon.

9. The method of claim 8, wherein said at least one metal comprises aluminum.

10. The method of claim 2, wherein said carbon nanotubes make up about 0.1% to about 35% by volume of said preform.

11. The method of claim 1, wherein said carbon nanotubes make up about 1% to about 15% by volume of said porous mass.

12. The method of claim 5, wherein said source of carbon also serves as said at least one coating.

13. The method of claim 2, wherein said mixture of carbon nanotubes and polymeric resin is shaped or rendered in the form of a prepreg.

14. The method of claim 2, wherein said reinforcement component further comprises, at least one other filler material comprising a plurality of finely divided bodies that are infiltrated into said preform by means of a carrier fluid.

15. The method of claim 3, wherein said at least one filler material comprises at least one substance selected from the group consisting of silicon carbide and boron carbide.

16. The method of claim 2, further comprising adding at least one filler material to said preform.

17. The method of claim 16, wherein at least one of said at least one filler mateials comrises a plurality of finely divided ceramic bodies comprising a morphology selected from the group consisting of particulate, fiber, platelets and flakes.

18. The method of claim 4, wherein said infiltrating occurs via capillarity.

19. The method of claim 4, wherein said infiltrating occurs with the assistance of an externally applied force.

20. A composite body, comprising:
(a) a reinforcement component comprising a plurality of carbon nanotubes; and
(b) a matrix component comprising at least one of elemental silicon and silicon carbide.

21. The composite body of claim 20, further comprising at least one coating that substantially shields or isolates said nanotubes from said silicon.

22. The composite body of claim 20, further comprising at least one zone of carbon disposed between said nanotubes and said matrix.

23. The composite body of claim 20, wherein said reinforcement component further comprises at least one filler.

24. The composite body of claim 21, wherein said matrix component comprises at least one metal other than silicon.

25. The composite body of claim 22, wherein said at least one metal comprises aluminum.

26. The composite body of claim 21, wherein said at least one coating comprises silicon carbide.

27. The composite body of claim 20, wherein said carbon nanotubes make up about 0.1% to about 35% by volume of said composite body.

28. The composite body of claim 20, wherein said carbon nanotubes make up about 1% to about 10% by volume of said composite body.

29. The composite body of claim 20, wherein said carbon nanotubes have a diameter that is less than about 500 nanometers.

30. The composite body of claim 20, wherein said carbon nanotubes have a diameter in the range of about 10 to 100 nanometers.

31. The composite body of claim 20, wherein said reinforcement component further comprises at least one other filler material.

32. The composite body of claim 31, wherein said at least one other filler material comprises at least one of silicon carbide and boron carbide.

33. The composite body of claim 31, wherein said at least one other filler material comprises a morphology selected from the group consisting of particulate, fiber, platelets and flakes.

34. The composite body of claim 31, wherein said at least one other filler material comprises carbon fibers.

35. The composite body of claim 31, wherein said reinforcement component makes up at least about 10 vol % of said composite body.

36. The composite body of claim 31, wherein said reinforcement component makes up as much as about 80 vol % of said composite body.

37. The composite body of claim 34, wherein said reinforcement component is present as at least one sheet or layer comprising said carbon nanotubes.
